(19) United States
(12) Patent Application Publication
(10) Pub. No.: US 2025/0386451 A1
(43) Pub. Date: Dec. 18, 2025

(54) EXTERNAL-STORAGE-DRIVE COOLING DEVICE

(71) Applicants: Paul T. Boggs, Alpine, UT (US); Codruta D. Boggs, Alpine, UT (US)

(72) Inventors: Paul T. Boggs, Alpine, UT (US); Codruta D. Boggs, Alpine, UT (US)

(21) Appl. No.: 18/743,098

(22) Filed: Jun. 13, 2024

(51) Int. Cl. H05K 7/20

(52) U.S. Cl. CPC H05K 7/20136

(57) ABSTRACT

An apparatus for cooling an external storage drive is disclosed. In one embodiment, such an apparatus includes a base unit having one or more fans configured to push air into an enclosure of an external storage drive. The base unit is also configured to physically support the external storage drive. A top unit having one or more fans is configured to pull air out of the enclosure. The top unit is configured to reside on a top surface of the external storage drive. The base unit and top unit are configured to cooperatively work together to circulate a stream of air through the enclosure, thereby providing additional cooling and heat removal from the external storage drive. A corresponding method is also disclosed.

### BACKGROUND

### Field of the Invention

This invention relates to apparatus and methods for cooling external storage drives such as external hard drives.

### Background of the Invention

External storage drives continue to expand in capacity, with manufacturers consistently pushing the boundaries to offer larger and larger options to meet ever increasing demands for digital storage. This trend reflects the exponential growth of digital data generated by entities such as individuals, businesses, and organizations. Today, these entities can easily access external storage drives with many terabytes of capacity, enabling them to store vast collections of multimedia files, extensive archives, and backups of critical data.

Nevertheless, as external storage drives continue to increase in size (e.g., storage capacity) and handle more intensive data processing and data transfer rates, the drives may generate additional heat. This heat may potentially affect the performance and reliability of the external storage drives. For example, excessive heat may lead to increased wear and tear on the drive's components, potentially reducing the lifespan of the drive and increasing the risk of data loss or drive failure.

### SUMMARY

The invention has been developed in response to the present state of the art and, in particular, in response to the problems and needs in the art that have not yet been fully solved by currently available apparatus and methods. Accordingly, apparatus and methods in accordance with the invention have been developed to improve cooling of external storage drives. The features and advantages of the invention will become more fully apparent from the following description and appended claims, or may be learned by practice of the invention as set forth hereinafter.

Consistent with the foregoing, an apparatus for cooling an external storage drive is disclosed. In one embodiment, such an apparatus includes a base unit having one or more fans configured to push air into an enclosure of an external storage drive. The base unit is also configured to physically support the external storage drive. A top unit having one or more fans is configured to pull air out of the enclosure. The top unit is configured to reside on a top surface of the external storage drive. The base unit and top unit are configured to cooperatively work together to circulate a stream of air through the enclosure, thereby providing additional cooling and heat removal from the external storage drive.

In certain embodiments, the base unit includes a filter that is configured to clean air that passes through the base unit. This may enable the apparatus to perform dual functions of not only cooling the external storage drive, but also cleaning the air of the environment in which the external storage drive resides. Furthermore, in certain embodiments, the base unit widens at a bottom thereof to provide more stability to the base unit and the external storage drive residing thereon. This may prevent or reduce any tendency of the external storage drive to topple over when resting on the base unit.

In certain embodiments, the base unit includes a bracket to retain the external storage drive. This may ensure that the external storage drive stays coupled to the base unit. This bracket may take on various different forms. In certain embodiments, a width of the bracket is made to be adjustable to accommodate external storage drives of different dimensions. In other embodiments, the width of the bracket is fixed to accommodate a specific external storage drive or drives of known dimensions. Similarly, in certain embodiments, the top unit may also include a bracket to retain the top unit on the external storage drive. This bracket may also, in certain embodiments, be fixed or adjustable to accommodate external storage drives of different dimensions.

A corresponding method is also disclosed and claimed herein.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is a perspective view showing one embodiment of cooling device in accordance with the invention for cooling an external storage drive;

FIG. 2 is a perspective view showing air flow created by the cooling device through the external storage drive;

FIG. 3 is a perspective view showing one embodiment of a cooling device having a stand to support a top unit relative to a base unit;

FIGS. 4A and 4B show various possible contemplated shapes and configurations for the base unit and/or top unit;

FIGS. 5A and 5B show other possible contemplated shapes and configurations for the base unit and/or top unit;

FIG. 6 is a cross-sectional side view showing various brackets that may be used to couple a base unit and top unit to an external storage drive; and

FIG. 7 shows various modifications that may be made to the base unit and also potentially applied to the top unit.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

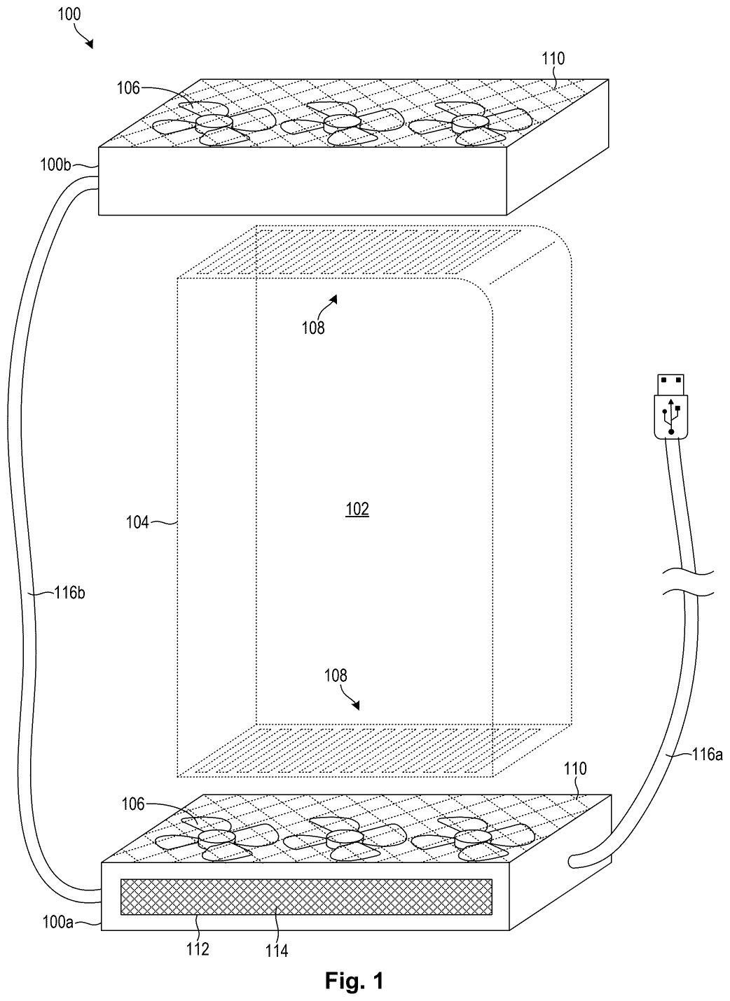

Referring to FIG. 1, as previously mentioned, as external storage drives continue to increase in size (e.g., storage capacity) and handle more intensive data processing and data transfer rates, the external storage drives may generate additional heat. This heat may potentially affect the performance and reliability of the external storage drives. For example, excessive heat may lead to increased wear and tear on the drive's components, potentially reducing the lifespan of the external storage drive and increasing the risk of data loss or drive failure. Thus, apparatus and methods are needed to deal with the additional heat that is generated in order to prolong the life of external storage drives and prevent potential data loss.

FIG. 1 is a perspective view showing one embodiment of a cooling device 100 for dissipating heat from an external storage drive 102 such as an external hard drive. As shown, the cooling device 100 includes a base unit 100a for pushing air into an enclosure 104 of the external storage drive 102, and a top unit 100b for pulling air out of the enclosure 104. The base unit 100a includes one or more fans 106 for pushing air into the enclosure 104 and the top unit 100b similarly includes one or more fans 106 for pulling air out of the enclosure 104. The term “fan” is used broadly herein to encompass any type of air moving mechanism. Thus, the base unit 100a and the top unit 100b may work together cooperatively to circulate a stream of air through the enclosure 104 of the external storage drive 102. As shown, the enclosure 104 of the external storage drive 102 may in certain embodiments include a screen 108, mesh 108, or slatted openings 108 on a top and bottom thereof to enable air to flow into and out of the enclosure 104 and thereby cool or dissipate heat from internal components (not shown) of the external storage drive 102.

The base unit 100a and top unit 100b are shown separated from the external storage drive 102 for illustration purposes. However, in practice, the external storage drive 102 may rest on the base unit 100a and the top unit 100b may rest on the top of the external storage drive 102. Thus, the base unit 100a may be designed to provide a stable platform for the external storage drive 102 as well as support the weight of the external storage drive 102. In certain embodiments, a screen 110 or louvered surface 110 of the base unit 100a may be designed to provide the stable platform and support base, while also allowing air to pass therethrough.

In certain embodiments, because the base unit 100a may reside on a flat surface such as a desktop or table, the base unit 100a may be designed to draw air into the base unit 100a from a side thereof by way of an air intake 112. In certain embodiments, this air intake 112 may be equipped with a filter 114 (e.g., mechanical filter, activated carbon filer, HEPA filter, UV-C filter, electrostatic filter, ionic filter, hybrid filter, etc.) to clean the air as it passes through the base unit 100a. The choice of air filter 114 may depend on factors such as specific contaminants present in the air, size of particles to be captured, desired level of filtration efficiency, and/or the like. Thus, the cooling device 100 may in certain embodiments serve dual purposes in both cooling the external storage drive 102 while also cleaning the air of the environment in which the external storage drive 102 resides.

As shown in FIG. 1, in certain embodiments, an electrical cord 116a may extend from the base unit 100a to transfer power to the base unit 100a from an external receptacle. In certain embodiments, the external receptacle is a USB port although a conventional electrical receptacle may also be used with or without an adapter to reduce voltage and/or convert AC electrical power to DC. In certain embodiments, an electrical cord 116b may connect the base unit 100a to the top unit 100b to transfer power therebetween, thereby also providing power to the top unit 100b.

When plugged in, the cooling device 100 may in certain embodiments be configured to run continuously to circulate air through the enclosure 104. Alternatively, the cooling device 100 may be automatically switched on or off as needed to cool the external storage drive 102. For example, a temperature sensor in or near the external storage drive 102 may sense the temperature off the external storage drive 102 to activate the base unit 100a and/or top unit 100b. The base unit 100a and top unit 100b may be activated together or potentially independently depending on how much cooling is needed. In other embodiments, software may monitor the temperature of the external storage drive 102 and activate the base unit 100a and/or top unit 100b through the very same USB (or other) cables 116a, 116b that are used to power the base unit 100a and/or top unit 100b. These represent just a few examples of ways to control and power the cooling device 100 and are not intended to be limiting.

Various design and engineering approaches may be used with the fans 106 to reduce noise while maintaining effective airflow. For example, the fan blades may be shaped to reduce turbulence and air noise generated as the fans 106 spin; the fan blades may be properly balanced to reduce vibration and noise; and the speed of the fans 106 may be tuned to provide adequate airflow while minimizing noise. The fan motors may also be designed to have low friction and minimal vibration, and rubber mountings may be used where appropriate to absorb vibrations. The enclosures for the base unit 100a and top unit 100b may also in certain embodiments use sound absorbing or dampening materials to reduce noise, and controls such as pulse width module (PWM) controls may enable the speed of the fans 106 to be adjusted dynamically to reduce noise during periods of low demand.

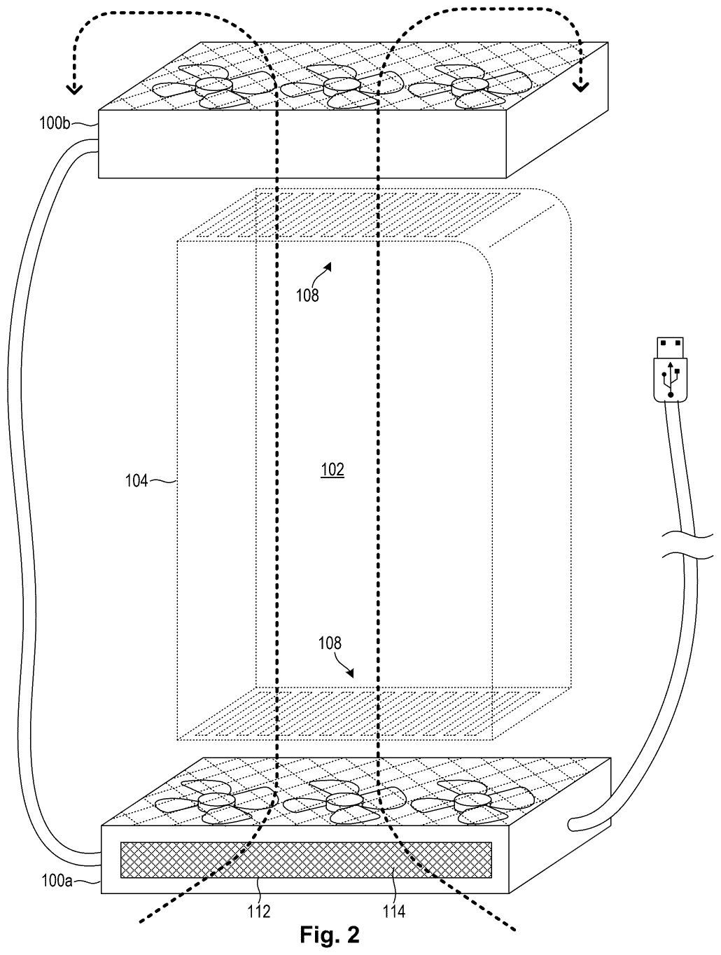

Referring to FIG. 2, as indicated above, the base unit 100a and the top unit 100b may work together cooperatively to circulate a stream 200 of air through the enclosure 104 of the external storage drive 102. As shown in FIG. 2, air may enter the base unit 100a by way of the air intake 112 and filter 114 and be pushed through the screen 108 or slatted openings 108 of the enclosure 104. The air may travel through the enclosure 104 and be pulled, by the top unit 100b, through the upper screen 108 or slatted openings 108 of the enclosure 104. The air may then be expelled into the surrounding environment where it may once again be circulated into and cleaned by the base unit 100a.

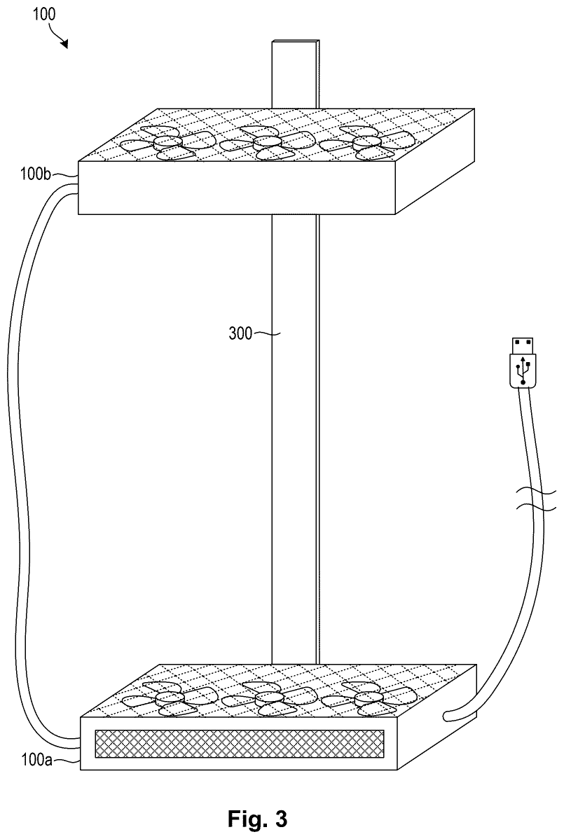

Referring to FIG. 3, in certain embodiments in accordance with the invention, the base unit 100a and top unit 100b may be coupled together in a way that provides support for the top unit 100b. This may prevent the top unit 100b from toppling off of the external storage drive 102 and constrain movement between the base unit 100a and the top unit 100b. FIG. 3 is a perspective view showing one contemplated embodiment of a cooling device 100 having a stand 300 to support the top unit 100b relative to the base unit 100a. The external storage drive 102 may be placed on the base unit 100a and the top unit 100b may be lowered or slid on the stand 300 until it resides immediately above the external storage drive 102. This may also allow the external storage drive 102 to be removed from the cooling device 100 without having to remove the top unit 100b. The top unit 100b may slide up and down on the stand 300 to accommodate external storage drives 102 of different dimensions. This represents just one example of a stand 300 or support 300 and is not intended to be limiting.

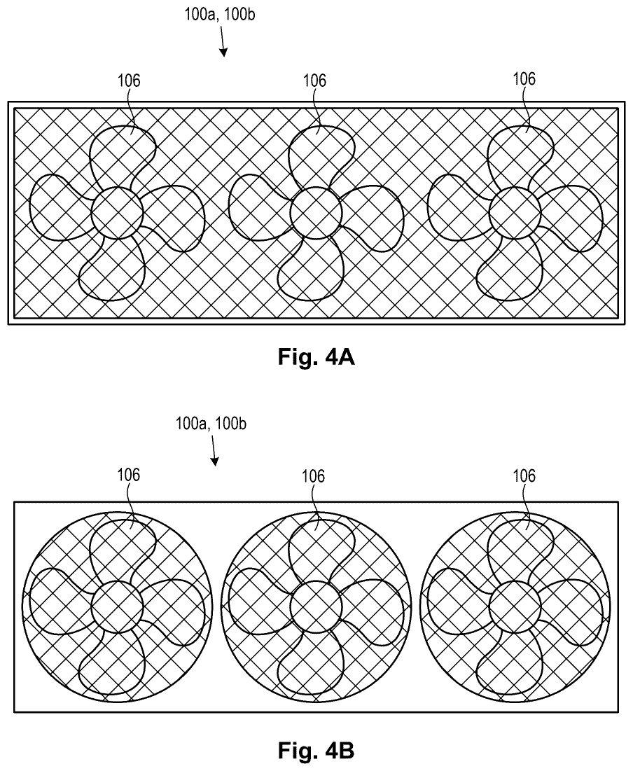

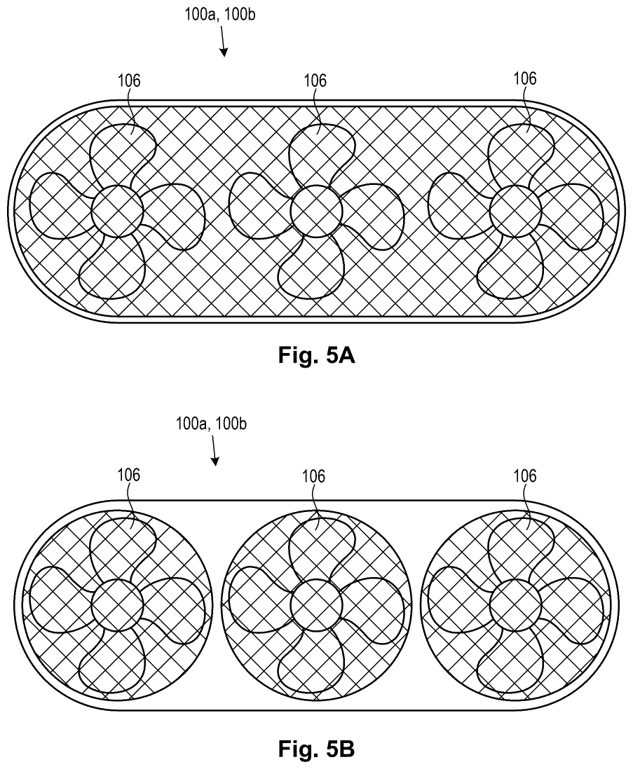

Referring to FIGS. 4A through 5B, the base unit 100a and top unit 100b may take on various different shapes and configurations. In certain embodiments, the base unit 100a and or top unit 100b may be shaped to match or substantially match the footprint of the external storage drive 102. Some external storage drives 102 may have substantially curved or rounded ends whereas others may have more squared ends. The shape (i.e., top or bottom view) of the base unit 100a and/or top unit 100b may in certain embodiments be configured to largely match these footprints. The footprint of the base unit 100a and/or top unit 100b may in certain embodiments be roughly the same size as the footprint of the external storage drive 102, although the footprint of the base unit 100a and/or top unit 100b may also be somewhat larger or smaller if desired depending on the configuration.

FIGS. 4A and 4B show a top view of one contemplated embodiment of a base unit 100a and/or top unit 100b having substantially squared ends. As shown, a screen or mesh covering the base unit 100a and/or top unit 100b may encompass most of its surface area (FIG. 4A), or may only cover areas immediately above the fans (FIG. 4B). FIGS. 5A and 5B show a top view of one contemplated embodiment of a base unit 100a and/or top unit 100b having rounded or curved ends. Similar to the previous example, a screen or mesh covering the base unit 100a and/or top unit 100b may encompass most of its surface area (FIG. 5A) or only cover areas immediately above the fans (FIG. 5B). These embodiments are presented by way of example and not intended to be limiting. Other shapes and configurations are possible or the embodiments shown in FIGS. 4A through 5B may be combined to create a hybrid embodiment, such as a footprint with one squared end and one rounded end as is common with some external storage drives 102.

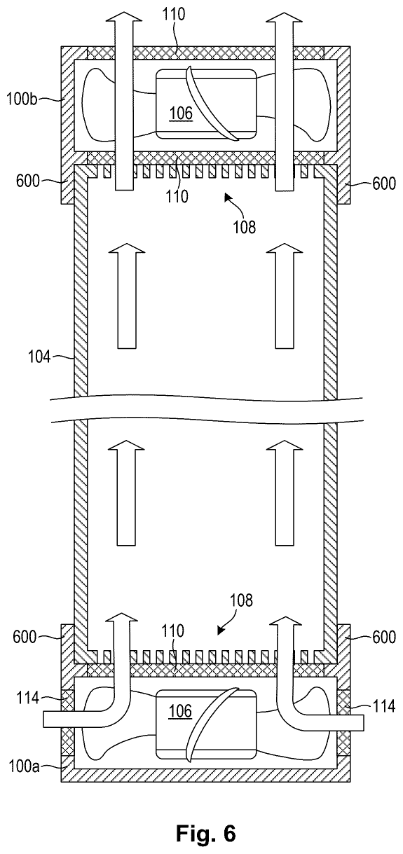

Referring to FIG. 6, a cross-sectional side view showing one embodiment of a base unit 100a, an enclosure 104 of an external storage drive 102, and a top unit 100b is illustrated. Airflow is shown through the base unit 100a, enclosure 104, and top unit 100b This embodiment shows various brackets 600 that may be used to couple a base unit 100a and a top unit 100b to an external storage drive 102. In certain embodiments, it may be advantageous to more closely couple the enclosure 104 of the external storage drive 102 to the base unit 100a and top unit 100b respectively. This may prevent or reduce the tendency of the external storage drive 102 to topple over, prevent the external storage drive 102 from sliding off of the base unit 100a, and/or prevent the top unit 100b from sliding off of the enclosure 104.

As shown, in certain embodiments, the base unit 100a may be equipped with one or more brackets 600 that may keep the enclosure 104 on the base unit 100a. In certain embodiments, the brackets 600 are simply a lip or ridge of some desired height (e.g., one centimeter) around a perimeter of a top surface of the base unit 100a that is configured to surround a bottom footprint of the enclosure 104. The brackets 600 may surround all or part of the bottom footprint of the enclosure 104. This may keep the enclosure 104 in place on the base unit 100a and provide the benefits previously described herein.

Similarly, the top unit 100b may also include one or more brackets 600 that may keep the top unit 100b on the enclosure 104. Like the previous example, the brackets 600 may simply be a lip or ridge of some desired height around a perimeter of a bottom surface of the top unit 100b that is configured to encompass the top of the enclosure 104. The brackets 600 may surround all or part of the top of the enclosure 104. This may keep the top unit 100b in place on the enclosure 104 to provide the benefits previously described herein.

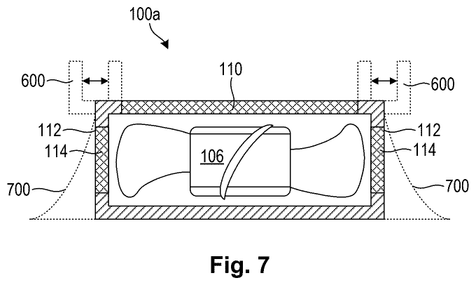

Referring to FIG. 7, in certain embodiments, the base unit 100a may be designed with a wider base to provide more stability and to prevent or reduce the tendency of the external storage drive 102 to topple over when resting on the base unit 100a. For example, the base unit 100a may in certain embodiments be designed to have a wider contour 700 at a bottom thereof to provide additional stability. In such an embodiment, the air intake 112 and filter 114 may be redesigned to fit the wider contour 700. The shape of the illustrated contour 700 is presented by way of example and is not intended to be limiting.

Similarly, in certain embodiments, the brackets 600 on the base unit 100a may be redesigned to be adjustable to accommodate external storage drives 102 of different dimensions. For example, the brackets 600 may, in certain embodiments, have a range of possible positions or widths to accommodate external storage drives 102 of different widths. The brackets 600 may, in certain embodiments, slide with respect to the rest of the base unit 100a to achieve these different widths and/or may be fixed or snapped to different positions to achieve these widths. This may make the cooling device 100 more universal to different types and dimensions of external storage drives 102. In certain embodiments, adjustable brackets 600 may also be incorporated into the top unit 100b for similar reasons.

In the above disclosure, reference has been made to the accompanying drawings which is shown by way of illustration specific implementations in which the disclosure may be practiced. It is understood that other implementations may be utilized and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

While various embodiments of the present disclosure have been described above, it should be understood that they have been presented by way of example only and not limitation. It will be apparent to persons skilled in the relevant art that various changes in form and detail can be made therein without departing from the spirit and scope of the disclosure. Thus, the breadth and scope of the present disclosure should not be limited by any of the above-described exemplary embodiments, but should be defined only in accordance with the following claims and their equivalents. The foregoing description has been presented for the purposes of illustration and description. It is not intended to be exhaustive or to limit the disclosure to the precise form disclosed. Many modifications and variations are possible in light of the above teachings. Further, it should be noted that any or all of the aforementioned alternate implementations may be used in any combination desired to form additional hybrid implementations of the disclosure.

1. An apparatus for cooling an external storage drive, the apparatus comprising:
a base unit comprising at least one fan configured to push air into an enclosure of external storage drive, the base unit further configured to physically support the external storage drive;
a top unit comprising at least one fan configured to pull air out of the external storage drive, the top unit configured to reside on a top surface of the external storage drive; and
the base unit and top unit configured to work together to circulate a stream of air through the external storage drive.

2. The apparatus of claim 1, wherein the base unit further comprises a filter to clean air that passes therethrough.

3. The apparatus of claim 1, wherein the base unit widens at a bottom thereof to provide stability to the base unit.

4. The apparatus of claim 1, wherein the base unit comprises a bracket to retain the external storage drive.

5. The apparatus of claim 4, wherein a width of the bracket is adjustable to accommodate different external storage drive dimensions.

6. The apparatus of claim 4, wherein a width of the bracket is fixed.

7. The apparatus of claim 1, wherein the top unit comprises a bracket to retain the top unit on the external storage drive.

8. The apparatus of claim 7, wherein a width of the bracket is adjustable to accommodate different external storage drive dimensions.

9. The apparatus of claim 1, further comprising an electrical cord to transfer power between the base unit and the top unit.

10. The apparatus of claim 1, further comprising an electrical cord to transfer power from a receptacle to the base unit.

11. A method for cooling an external storage drive, the method comprising:
pushing, using a base unit that comprises at least one fan and that physically supports an external storage drive, air into the external storage drive;
pulling, using a top unit that comprises at least one fan and that resides on a top surface of the external storage drive, air out of the external storage drive; and
cooperatively circulating a stream of air through the external storage drive using the base unit and top unit.

12. The method of claim 11, wherein pushing the air comprises pulling the air through a filter to clean the air.

13. The method of claim 11, wherein the base unit widens at a bottom thereof to provide stability to the base unit.

14. The method of claim 11, further comprising retaining the external storage drive on the base unit using a bracket.

15. The method of claim 14, wherein using a bracket comprises using a bracket with an adjustable width to accommodate different external storage drive dimensions.

16. The method of claim 14, wherein using a bracket comprises using a bracket with a fixed width.

17. The method of claim 11, further comprising coupling the top unit to the external storage drive using a bracket.

18. The method of claim 17, wherein using a bracket comprises using a bracket with an adjustable width to accommodate different external storage drive dimensions.

19. The method of claim 11, further comprising transferring power between the base unit and the top unit using an electrical cord.

20. The method of claim 11, further comprising transferring power from a receptacle to the base unit using an electrical cord.
